(19) United States
(12) Patent Application Publication
(10) Pub. No.: US 2026/0041166 A1
(43) Pub. Date: Feb. 12, 2026

(54) AEROSOL-GENERATING DEVICE

(71) Applicant: KT&G CORPORATION, Daejeon (KR)

(72) Inventors: Chulho JANG, Buchun-si (KR); Youngmin WOO, Hwasung-si (KR)

(73) Assignee: KT&G CORPORATION, Daejeon (KR)

(21) Appl. No.: 19/255,409

(22) Filed: Jun. 30, 2025

(30) Foreign Application Priority Data
Aug. 9, 2024 (KR) 10-2024-0106567

(51) Int. Cl. A24F 40/57; A24F 40/10; A24F 40/44; A24F 40/46; A24F 40/485; H05B 3/00

(52) U.S. Cl. CPC A24F 40/57; A24F 40/10; A24F 40/44; A24F 40/46; A24F 40/485; H05B 3/0071; H05B 2214/04

(57) ABSTRACT

An aerosol-generating device is disclosed. The aerosol-generating device includes a storage chamber storing an aerosol-generating substance, a wick that is in communication with the storage chamber, a heating element that is in contact with the wick and contains nanoparticles generating heat through surface plasmon resonance, and a light source configured to emit light toward the heating element. The heating element includes a first part receiving light emitted from the light source and a second part disposed outside the first part and having a plurality of holes formed therein.

### CROSS-REFERENCE TO RELATED APPLICATION

This application claims priority from Korean Patent Application No. 10-2024-0106567, filed on Aug. 9, 2024, in the Korean Intellectual Property Office, the disclosure of which is incorporated herein by reference in its entirety.

### BACKGROUND OF THE DISCLOSURE

### 1. Field of the disclosure The present disclosure relates to an aerosol-generating device.

### 2. Description of the Related Art

An aerosol-generating device is a device that extracts certain components from a medium or a substance by forming an aerosol. The medium may contain a multicomponent substance. The substance contained in the medium may be a multicomponent flavoring substance. For example, the substance contained in the medium may include a nicotine component, an herbal component, and/or a coffee component. Recently, various studies on aerosol-generating devices have been conducted.

A device utilizing surface plasmon resonance (SPR) technology to heat an aerosol-generating substance has been proposed. In an aerosol-generating device employing SPR-based heating, an aerosol is primarily generated in a region where an SPR heating element is in contact with a wick. However, the aerosol generated in the region where the SPR heating element is in contact with the wick may not easily move into an airflow path, which results in an insufficient aerosol output. In addition, it may take a long time for the temperature of the liquid aerosol-generating substance in the region where the SPR heating element is in contact with the wick to reach a vaporization temperature.

### SUMMARY OF THE DISCLOSURE

It is an object of the present disclosure to solve the above and other problems.

It is another object of the present disclosure to provide an aerosol-generating device including a surface plasmon resonance (SPR) heating element that includes a first part on which light emitted from a light source is incident and a second part disposed outside the first part and having a plurality of holes formed therein.

It is still another object of the present disclosure to provide an aerosol-generating device including an SPR heating element that includes a plurality of holes formed in a region outside an optical path and allowing a wick and an atomization chamber to communicate with each other therethrough.

It is still another object of the present disclosure to provide an aerosol-generating device including an SPR heating element that includes a third part extending outward from the first part, on which light is incident, across the second part having the plurality of holes.

It is still another object of the present disclosure to provide an aerosol-generating device including a structure that surrounds the first part, on which light is incident, and extends from the first part toward the light source to seal the optical path from the outside.

It is still another object of the present disclosure to provide an aerosol-generating device including an SPR heating element that includes a plurality of first parts, on each of which light emitted from a respective one of a plurality of light sources is incident and which is disposed to be spaced apart from each other.

It is still another object of the present disclosure to provide an aerosol-generating device in which the operation of the plurality of light sources is controlled based on a target temperature or a target heating rate of the heating element.

In accordance with an aspect of the present disclosure for accomplishing the above and other objects, there is provided an aerosol-generating device including a storage chamber storing an aerosol-generating substance, a wick that is in communication with the storage chamber, a heating element that is in contact with the wick and contains nanoparticles generating heat through surface plasmon resonance, and a light source configured to emit light toward the heating element, wherein the heating element includes a first part receiving light emitted from the light source and a second part disposed outside the first part and having a plurality of holes formed therein.

Additional applications of the present disclosure will become apparent from the following detailed description. However, because various changes and modifications will be clearly understood by those skilled in the art within the spirit and scope of the present disclosure, it should be understood that the detailed description and specific embodiments, such as preferred embodiments of the present disclosure, are merely given by way of example.

### BRIEF DESCRIPTION OF THE DRAWINGS

The above and other objects, features, and other advantages of the present disclosure will be more clearly understood from the following detailed description taken in conjunction with the accompanying drawings, in which:

FIG. 1 is a block diagram of an aerosol-generating device according to an embodiment of the present disclosure;

FIG. 2 is a front perspective view of an aerosol-generating device according to an embodiment of the present disclosure;

FIG. 3 is a cross-sectional view of the aerosol-generating device according to the embodiment of the present disclosure when viewed from the front;

FIG. 4 is an exploded perspective view of a storage chamber, a wick, and a heating element of the aerosol-generating device according to the embodiment of the present disclosure;

FIG. 5 is a perspective view showing the heating element of the aerosol-generating device according to the embodiment of the present disclosure;

FIG. 6 is an enlarged cross-sectional view showing the arrangement of the storage chamber, the wick, and the heating element in the aerosol-generating device according to the embodiment of the present disclosure;

FIG. 7 is a cross-sectional view showing an optical path and an aerosol generation direction in the aerosol-generating device according to the embodiment of the present disclosure;

FIG. 8 is a perspective view showing a heating element of an aerosol-generating device according to another embodiment of the present disclosure;

FIG. 9 is an enlarged cross-sectional view showing the arrangement of the storage chamber, the wick, and the heating element in the aerosol-generating device according to the other embodiment of the present disclosure; and FIG. 10 is a cross-sectional view showing an optical path and an aerosol generation direction in the aerosol-generating device according to the other embodiment of the present disclosure.

### DETAILED DESCRIPTION OF THE PREFERRED EMBODIMENTS

Hereinafter, the embodiments disclosed in the present specification will be described in detail with reference to the accompanying drawings. The same or similar elements are denoted by the same reference numerals even though they are depicted in different drawings, and redundant descriptions thereof will be omitted. With regard to the description of the drawings, similar reference numerals may be used to refer to similar or related elements.

In the following description, with respect to constituent elements used in the following description, the suffixes “module” and “unit” are used only in consideration of facilitation of description, and do not have mutually distinguished meanings or functions. As used herein, the suffix “module” or “unit” may include a unit implemented in hardware, software, or firmware, and may be used interchangeably with other terms, for example, “logic,” “logic block,” “part,” or “circuitry. ” A “module” or a “unit” may be a single integral component, or a minimum unit or part thereof, adapted to perform one or more functions. For example, the “module” or the “unit” may be implemented in the form of an application-specific integrated circuit (ASIC).

In addition, in the following description of the embodiments disclosed in the present specification, a detailed description of known functions and configurations incorporated herein will be omitted when the same may make the subject matter of the embodiments disclosed in the present specification rather unclear. In addition, the accompanying drawings are provided only for a better understanding of the embodiments disclosed in the present specification and are not intended to limit the technical ideas disclosed in the present specification. Therefore, it should be understood that the accompanying drawings include all modifications, equivalents, and substitutions within the scope and spirit of the present disclosure.

It will be understood that although the terms “first”, “second”, etc., may be used herein to describe various components, these components should not be limited by these terms. These terms are only used to distinguish one component from another component.

It will be understood that when a component is referred to as being “connected to” or “coupled to” another component, it may be directly connected to or coupled to another component, or intervening components may be present. On the other hand, when a component is referred to as being “directly connected to” or “directly coupled to” another component, there are no intervening components present.

As used herein, the singular form is intended to include the plural forms as well, unless the context clearly indicates otherwise.

Embodiments as set forth herein may be implemented as software including one or more instructions that are stored in a storage medium (e.g., a memory 17) that is readable by a machine (e.g., the aerosol-generating device 1). For example, a processor (e.g., the controller 12) of the machine (e.g., the aerosol-generating device 1) may invoke at least one of the one or more instructions stored in the storage medium, and may execute the same. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

In the present disclosure, the directions of the aerosol-generating device 1 may be defined based on the orthogonal coordinate system. In the orthogonal coordinate system, the x-axis direction may be defined as a leftward-rightward direction of the aerosol-generating device 1. The y-axis direction may be defined as a forward-backward direction of the aerosol-generating device 1. The z-axis direction may be defined as an upward-downward direction of the aerosol-generating device 1.

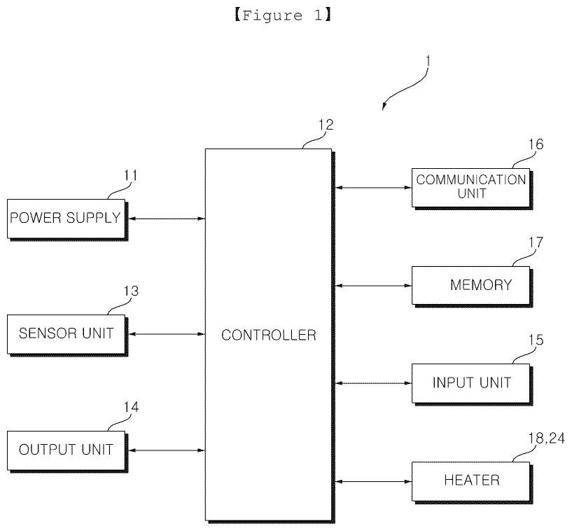

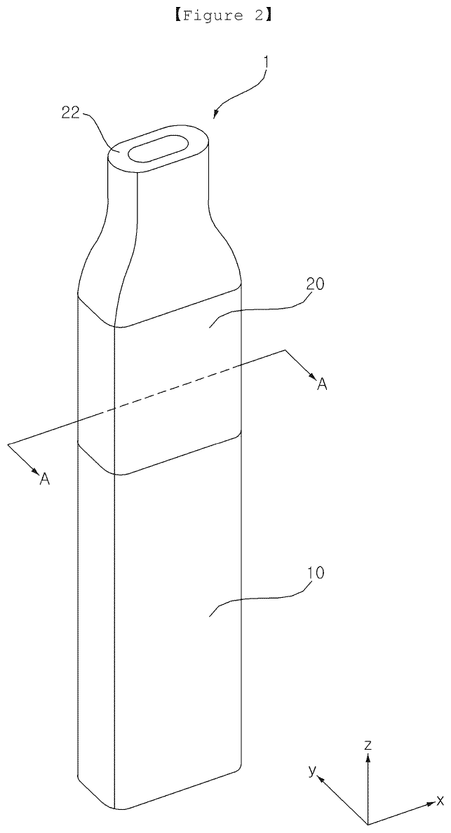

FIG. 1 is a block diagram of an aerosol-generating device according to an embodiment.

According to one embodiment, the aerosol-generating device 1 may include a power supply 11, a controller 12, a sensor unit 13, an output unit 14, an input unit 15, a communication unit 16, a memory 17, and/or a heater 18 and 24. However, the components included in the aerosol-generating device 1 are not limited to those shown in FIG. 1. That is, it will be understood by those skilled in the art related to the present embodiment that some of the components shown in FIG. 1 may be omitted or new components may be further included depending on the design of the aerosol-generating device 1.

According to one embodiment, the sensor unit 13 may detect the state of the aerosol-generating device 1 or the state of the surroundings of the aerosol-generating device 1, and may transmit the detected information to the controller 12. For example, the sensor unit 13 may include a temperature sensor, a puff sensor, an insertion detection sensor, a reuse detection sensor, an overly moist state detection sensor, a cigarette identification sensor, a cartridge detection sensor, a cap detection sensor, and/or a movement detection sensor. Meanwhile, the sensor unit 13 may further include various sensors, such as a liquid residual quantity sensor for detecting the residual quantity of liquid in the cartridge and an immersion sensor for detecting immersion of the aerosol-generating device 1.

According to one embodiment, the temperature sensor may detect a temperature to which the heater 18 and 24 is heated. The aerosol-generating device 1 may include a separate temperature sensor for detecting the temperature of the heater 18 and 24, or the heater 18 and 24 itself may serve as a temperature sensor. In an example, the temperature sensor may be used to measure impedance for the heater 18. The impedance for the heater 18 may correlate with the temperature of the heater 18. The temperature sensor may measure current and/or voltage applied to the heater 18 (or an induction coil). The impedance for the heater 18 may be obtained based on the measured current and/or voltage. The controller 12 may estimate the temperature of the heater 18 based on the obtained impedance.

In an example, the temperature sensor may include a resistance element (e.g., a thermistor), the resistance value of which varies in response to changes in the temperature of the heater 18 and 24. The temperature sensor may output a signal corresponding to the resistance value of the resistance element, and the controller 12 may determine the temperature of the heater 18 and 24 and/or a change in the temperature of the heater 18 and 24 based on the signal corresponding to the resistance value.

In another example, the temperature sensor may include a sensor that detects the resistance value of the heater 18 and 24. The temperature sensor may output a signal corresponding to the resistance value of the heater 18 and 24, and the controller 12 may determine the temperature of the heater 18 and 24 and/or a change in the temperature of the heater 18 and 24 based on the signal corresponding to the resistance value.

According to one embodiment, the temperature sensor may detect the temperature of the power supply 11. The temperature sensor may be disposed adjacent to the power supply 11. For example, the temperature sensor may be attached to one surface of the power supply 11 (e.g., a battery) and/or may be mounted on one surface of a printed circuit board. In an example, the aerosol-generating device 1 may include a power supply protection circuit module (PCM), and the temperature sensor may be disposed adjacent to the power supply 11 together with the power supply protection circuit module.

According to one embodiment, the temperature sensor may be disposed in a housing (not shown) of the aerosol-generating device 1 to detect the internal temperature of the housing (not shown).

According to one embodiment, the puff sensor may detect a user's puff.

In an example, the puff sensor may include a pressure sensor. The pressure sensor may output a signal corresponding to the internal pressure of the aerosol-generating device 1, and the controller 12 may determine the user's puff based on the signal corresponding to the internal pressure. Here, the internal pressure of the aerosol-generating device 1 may correspond to the pressure of an airflow path through which gas flows. The puff sensor may be disposed corresponding to the airflow path through which gas flows in the aerosol-generating device 1.

In another example, the puff sensor may include a temperature sensor. When the user's puff occurs, temperature drop may temporarily occur in the airflow path, a space into which an aerosol-generating article is inserted (hereinafter referred to as an “insertion space”), and the heater 18 and 24. The controller 12 may determine the user's puff based on a signal corresponding to the temperature of the airflow path output from the temperature sensor.

In still another example, the puff sensor may include both a pressure sensor and a temperature sensor. In this case, the temperature sensor may measure temperature used to calibrate the internal pressure measured by the pressure sensor. In one example, the puff sensor may calibrate a signal corresponding to the internal pressure based on the temperature measured by the temperature sensor, and may output the calibrated signal. In another example, the puff sensor may output a signal corresponding to the temperature measured by the temperature sensor and a signal corresponding to the internal pressure measured by the puff sensor. In this case, the controller 12 may receive the signals, and may calibrate the signal corresponding to the internal pressure based on the signal corresponding to the temperature.

In still another example, the puff sensor may include a capacitance sensor. The capacitance sensor may also be called a cap sensor or a capacitive sensor. When the user's puff occurs, a temperature change and/or aerosol flow may occur in the insertion space of the aerosol-generating article, and accordingly, a dielectric constant in the insertion space may change. The controller 12 may determine the user's puff based on a signal corresponding to the dielectric constant in the insertion space output from the capacitance sensor.

The puff sensor is not limited to the examples described above, and may be implemented as various sensors for detecting the user's puff.

According to one embodiment, the insertion detection sensor may detect insertion and/or removal of the aerosol-generating article. The insertion detection sensor may be mounted adjacent to the insertion space. In addition, the insertion detection sensor may include any combination of the examples described above.

In an example, the insertion detection sensor may include a capacitance sensor. The capacitance sensor may include at least one conductor, and the at least one conductor may be disposed adjacent to the insertion space. When the aerosol-generating article is inserted into or removed from the insertion space, capacitance around the conductor may change. The controller 12 may determine insertion and/or removal of the aerosol-generating article based on a signal corresponding to the dielectric constant in the insertion space output from the capacitance sensor.

In another example, the insertion detection sensor may include an inductive sensor. The inductive sensor may include at least one coil, and the at least one coil may be disposed adjacent to the insertion space. If the aerosol-generating article (e.g., a wrapper of the aerosol-generating article) includes a conductor, when the aerosol-generating article is inserted into or removed from the insertion space, a change in magnetic field may occur around the coil through which current flows. The controller 12 may determine insertion and/or removal of the aerosol-generating article including a conductor based on the characteristics of the current output from or detected by the inductive sensor (e.g., frequency of alternating current, a current value, a voltage value, an inductance value, and an impedance value). Alternatively, a susceptor SUS or the like may be included in the aerosol-generating article (e.g., a medium portion of the aerosol-generating article). In this case, a change in magnetic field may also occur around the coil based on insertion or removal of the susceptor or the like into or from the insertion space, and the controller 12 may determine insertion and/or removal of the aerosol-generating article based on the characteristics of the current of the inductive sensor.

The insertion detection sensor is not limited to the examples described above, and may be implemented as various sensors (e.g., a proximity sensor) for detecting insertion and/or removal of the aerosol-generating article. In addition, the insertion detection sensor may include any combination of the examples described above. According to one embodiment, the insertion detection sensor may include a switch or the like for detecting pressing by the aerosol-generating article.

According to one embodiment, the reuse detection sensor may detect whether the aerosol-generating article is being reused. In an example, the reuse detection sensor may be a color sensor for detecting the color of the aerosol-generating article. If the aerosol-generating article is used by the user, a change in the color of a portion of the wrapper may occur due to the generated aerosol or heating. The color sensor may output a signal corresponding to an optical characteristic (e.g., wavelength of light) corresponding to the color of the wrapper based on the light reflected from the wrapper. When a change in the color of a portion of the wrapper is detected, the controller 12 may determine that the aerosol-generating article inserted into the insertion space has already been used.

According to one embodiment, the overly moist state detection sensor may detect whether the aerosol-generating article is in an overly moist state. For example, the overly moist state detection sensor may include a capacitance sensor. The capacitance sensor may include at least one conductor disposed adjacent to the insertion space. The controller 12 may determine whether the aerosol-generating article is in an overly moist state based on the level of a signal corresponding to the dielectric constant or the like output from the capacitance sensor. In an example, the controller 12 may check a level range within which the level of the signal is included based on a look-up table, and may determine the moisture content of the aerosol-generating article based on the checked level range.

According to one embodiment, the cigarette identification sensor may detect whether the aerosol-generating article is authentic and/or may detect the type of the aerosol-generating article.

In an example, the cigarette identification sensor may include an optical sensor for detecting an identification material (or an identification mark) located on the outer surface (e.g., the wrapper) of the aerosol-generating article. The optical sensor may radiate light toward the identification material (or the identification mark) of the aerosol-generating article, and may detect whether the aerosol-generating article is authentic and/or may detect the type of the aerosol-generating article based on the reflected light. For example, the identification material may include a material (i.e., a luminous material) that emits light of a specific wavelength band based on the light radiated thereto. The controller 12 may determine whether the aerosol-generating article is authentic and/or may determine the type of the aerosol-generating article based on the range of the wavelength.

In another example, the cigarette identification sensor may include a capacitance sensor. The dielectric constant in the insertion space may vary depending on the type of the aerosol-generating article inserted into the insertion space. The controller 12 may determine whether the aerosol-generating article is authentic and/or may determine the type of the aerosol-generating article based on a signal corresponding to the dielectric constant or the like in the insertion space output from the capacitance sensor.

In still another example, the cigarette identification sensor may include an inductive sensor. If a conductor is included in the wrapper and/or inner portion (e.g., the medium portion) of the aerosol-generating article inserted into the insertion space, when the aerosol-generating article is inserted into the insertion space, the characteristics of the current detected by the inductive sensor (e.g., frequency of alternating current, a current value, a voltage value, an inductance value, and an impedance value) may vary depending on the type of the aerosol-generating article inserted into the insertion space. The controller 12 may determine whether the inserted aerosol-generating article is authentic and/or may determine the type of the inserted aerosol-generating article based on the characteristics of the current output from or detected by the inductive sensor.

The cigarette identification sensor is not limited to the examples described above, and may be implemented as various sensors for detecting whether the aerosol-generating article is authentic and/or detecting the type of the aerosol-generating article. In addition, the cigarette identification sensor may include any combination of the examples described above.

According to one embodiment, the cartridge detection sensor may detect mounting and/or removal of the cartridge. For example, the cartridge detection sensor may include an inductive sensor, a capacitance sensor, a resistance sensor, a Hall sensor (Hall IC), and/or an optical sensor.

According to one embodiment, the cap detection sensor may detect mounting and/or removal of the cap. For example, the cap detection sensor may include an inductive sensor, a capacitance sensor, a resistance sensor, a contact sensor, a Hall sensor (Hall IC), and/or an optical sensor. The cap may cover at least a portion of the cartridge mounted in or inserted into the aerosol-generating device 1 or may cover at least a portion of the housing of the aerosol-generating device 1. When the cap is mounted in or removed from the housing, the cap detection sensor may output a signal corresponding to mounting or removal, and the controller 12 may determine mounting or removal of the cap based on the signal corresponding to mounting or removal.

According to one embodiment, the movement detection sensor may detect movement of the aerosol-generating device 1. The movement detection sensor may be implemented as at least one of an acceleration sensor or a gyro sensor.

According to one embodiment, the sensor unit 13 may further include at least one of a humidity sensor, an air pressure sensor, a magnetic sensor, a position sensor (global positioning system (GPS)), or a proximity sensor in addition to the sensors described above. The functions of the sensors can be intuitively deduced by those skilled in the art from the names thereof, and thus detailed descriptions thereof may be omitted.

According to one embodiment, the output unit 14 may output information about the state of the aerosol-generating device 1 to provide the same to the user. The output unit 14 may include, but is not limited to, a display, a haptic unit, and/or a sound output unit. For example, information about the aerosol-generating device 1 may include a charging/discharging state of the power supply 11 of the aerosol-generating device 1, a preheating state of the heater 18 and 24, an insertion/removal state of the aerosol-generating article and/or the cartridge, a mounting/removal state of the cap, or a state in which the use of the aerosol-generating device 1 is restricted (e.g., detection of an abnormal object). The display may visually provide the information about the state of the aerosol-generating device 1 to the user. For example, the display may include a light-emitting diode (LED), a liquid crystal display panel (LCD), and an organic light-emitting diode panel (OLED). If the display includes a touchpad, the display may also be used as the input unit 15. The haptic unit may haptically provide the information about the aerosol-generating device 1 to the user. For example, the haptic unit may include a vibration motor, a piezoelectric element, and an electrical stimulation device. The sound output unit may audibly provide the information about the aerosol-generating device 1 to the user. For example, the sound output unit may convert an electrical signal into an acoustic signal and may output the acoustic signal to the outside.

According to one embodiment, the power supply 11 may supply power used for operation of the aerosol-generating device 1. The power supply 11 may include one or more batteries. The power supply 11 may supply power so that the heater 18 and 24 is heated. In addition, the power supply 11 may supply power necessary for operation of the other components included in the aerosol-generating device 1, such as the controller 12, the sensor unit 13, the output unit 14, the input unit 15, the communication unit 16, and the memory 17. The power supply 11 may be a rechargeable battery or a disposable battery. For example, the power supply 11 may be a lithium polymer (LiPoly) battery without being limited thereto. The power supply 11 may be a replaceable (separation-type) battery (hereinafter referred to as a “removable battery”). The removable battery may be mounted in a battery accommodation portion provided in the aerosol-generating device 1 or may be removed from the battery accommodation portion. The removable battery may be charged in a wired and/or wireless manner.

According to one embodiment, the heater 18 and 24 may receive power from the power supply 11 to heat the aerosol-generating article (e.g., a cigarette) and/or a medium and/or an aerosol-generating substance in the cartridge. The aerosol-generating device 1 may include a heater 18 for heating the aerosol-generating article and/or a cartridge heater 24 for heating the cartridge (i.e., a solid and/or liquid medium).

According to one embodiment, the heater 18 and 24 may be an electro-resistive heater. For example, the electro-resistive heater may include an electrically resistive material such as a metal or a metal alloy including titanium, zirconium, tantalum, platinum, nickel, cobalt, chromium, hafnium, niobium, molybdenum, tungsten, tin, gallium, manganese, iron, copper, stainless steel, and nichrome. The electro-resistive heater may be implemented as a metal wire, a metal plate having an electrically conductive track disposed thereon, or a ceramic heating element.

According to one embodiment, the heater 18 and 24 may be an induction heater. For example, the induction heater may include a susceptor that generates heat through a magnetic field. A magnetic field may be generated by an induction coil by alternating current flowing through the induction coil. The magnetic field may pass through the heater, and an eddy current may be generated in the susceptor. The susceptor may be heated based on generation of the eddy current. According to one embodiment, the susceptor may be included in the inner portion (e.g., the medium portion) of the aerosol-generating article. In this case, the susceptor included in the inner portion of the aerosol-generating article may also be heated by the induction coil.

The heater 18 and 24 is not limited to the examples described above, and may include or be replaced with various heating methods, structures, and components for heating the aerosol-generating article and/or the cartridge.

According to one embodiment, the input unit 15 may receive information input from the user. For example, the input unit 15 may include a touch panel, a button, a keypad, a dome switch, a jog wheel, and a jog switch.

According to one embodiment, the memory 17 may be hardware storing various pieces of data processed in the aerosol-generating device 1. The memory 17 may store data processed and to be processed by the controller 12. For example, the memory 17 may include at least one type of storage medium among a flash memory type memory, a hard disk type memory, a multimedia card micro type memory, a card type memory (e.g., SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disc. For example, the memory 17 may store data on an operation time of the aerosol-generating device 1, the maximum number of puffs, the current number of puffs, at least one temperature profile, and the user's smoking pattern.

According to one embodiment, the communication unit 16 may include at least one component for communication with other electronic devices (e.g., a portable electronic device). For example, the communication unit 16 may include a Bluetooth communication unit, a Bluetooth low energy (BLE) communication unit, a near-field communication unit, a wireless local area network (WLAN) communication unit, a Zigbee communication unit, an infrared data association (IrDA) communication unit, a Wi-Fi direct (WFD) communication unit, an ultra-wideband (UWB) communication unit, an Ant+ communication unit, a cellular network communication unit, an Internet communication unit, and a computer network (e.g., LAN or WAN) communication unit.

According to one embodiment, the controller 12 may control the overall operation of the aerosol-generating device 1. For example, the controller 12 may include at least one processor. The controller 12 may be implemented as an array of a plurality of logic gates or may be implemented as a combination of a general-purpose microcontroller unit (MCU) (or a microprocessor) and a memory in which a program executable by the MCU is stored. It will be understood by those skilled in the art that the controller may also be implemented as other forms of hardware.

According to one embodiment, the controller 12 may control the supply of power from the power supply 11 to the heater 18 and 24 to control the temperature of the heater 18 and 24. The controller 12 may control the temperature of the heater 18 and 24 and/or power supplied to the heater 18 and 24 based on the temperature of the heater 18 and 24 detected by the temperature sensor (e.g., the sensor unit 13). The controller 12 may control the temperature of the heater 18 and 24 and/or power supplied to the heater 18 and 24 based on the temperature profile and/or the power profile stored in the memory 17.

According to one embodiment, the controller 12 may control a power conversion circuit (not shown) electrically connected to the heater 18 and 24 and the power supply 11 to control power (e.g., voltage and/or current) supplied to the heater 18 and 24. For example, the power conversion circuit may include a DC/DC converter (e.g., a buck converter, a buck-boost converter, a boost converter, or a Zener diode) that converts power to be supplied to the heater 18 and 24 and a DC/AC converter (e.g., an inverter) that converts power to be supplied to the induction coil (not shown). The DC/AC converter may be implemented as a full-bridge circuit or a half-bridge circuit including a plurality of switching elements. For example, the power conversion circuit may include at least one switching element, such as a bipolar junction transistor (BJT) or a field effect transistor (FET).

According to one embodiment, the controller 12 may control the frequency and/or duty ratio of a current pulse input to at least one switching element of the power conversion circuit (not shown) to control the current and/or the voltage supplied to the heater 18 and 24. The duty ratio for the on/off operation of the switching element may correspond to a ratio of the voltage output from the power conversion circuit to the voltage output from the power supply 11.

According to one embodiment, the controller 12 may control power supplied to the heater 18 and 24 using at least one of a pulse width modulation (PWM) scheme or a proportional-integral-differential (PID) scheme. For example, the controller 12 may perform control using the PWM scheme such that a current pulse having a predetermined frequency and a predetermined duty ratio is supplied to the heater 18 and 24. The controller 12 may control the frequency and duty ratio of the current pulse to control power supplied to the heater 18 and 24. For example, the controller 12 may determine, based on the temperature profile, a target temperature to be controlled. The controller 12 may control power supplied to the heater 18 and 24 using the PID scheme, which is a feedback control scheme using a difference value between the temperature of the heater 18 and the target temperature, a value obtained by integrating the difference value with respect to time, and a value obtained by differentiating the difference value with respect to time.

According to one embodiment, the controller 12 may determine, based on the power profile, target power to be controlled. The controller 12 may control power supplied to the heater 18 and 24 so as to correspond to the preset target power over time.

According to one embodiment, the controller 12 may detect power supplied to the heater 18 and 24 to determine the user's puff. In more detail, the controller 12 may control power supplied to the heater 18 and 24 using the proportional-integral-differential (PID) scheme. When the user's puff occurs, temperature drop may temporarily occur in a space into which the aerosol-generating article is inserted (hereinafter referred to as an insertion space) and the heater 18 and 24. Accordingly, the power (or the current) supplied to the heater 18 and 24 may change during control of the power using the PID scheme. The controller 12 may determine the user's puff based on the change in the power controlled.

According to one embodiment, the controller 12 may prevent the heater 18 and 24 from overheating. For example, the controller 12 may control, based on the temperature of the heater 18 and 24 exceeding a preset limit temperature, operation of the power conversion circuit such that the amount of power supplied to the heater 18 and 24 is reduced or the supply of power to the heater 18 and 24 is interrupted.

According to one embodiment, the controller 12 may control charging/discharging of the power supply 11. For example, the controller 12 may check the temperature of the power supply 11 using the temperature sensor (e.g., the sensor unit 13). If the temperature of the power supply 11 is equal to or higher than a first limit temperature, the controller 12 may interrupt charging of the power supply 11. If the temperature of the power supply 11 is equal to or higher than a second limit temperature, the controller 12 may interrupt use of the power stored in the power supply 11 (e.g., discharging). The controller 12 may calculate the remaining amount of the power stored in the power supply 11. For example, the controller 12 may calculate the remaining capacity of the power supply 11 based on a voltage and/or current detection value of the power supply 11.

According to one embodiment, the controller 12 may control the supply of power to the heater 18 and 24 based on a result of the detection by the sensor unit 13.

According to one embodiment, the controller 12 may control the supply of power to the heater 18 and 24 based on insertion and/or removal of the aerosol-generating article into and/or from the insertion space. For example, upon determining that the aerosol-generating article has been inserted into the insertion space using the insertion detection sensor (e.g., the sensor unit 13), the controller 12 may perform control such that power is supplied to the heater 18 and 24. Upon determining that the aerosol-generating article has been removed from the insertion space using the insertion detection sensor (e.g., the sensor unit 13), the controller 12 may interrupt the supply of power to the heater 18 and 24. The controller 12 may determine that the aerosol-generating article has been removed from the insertion space when the temperature of the heater 18 and 24 is equal to or higher than a limit temperature or when the temperature change slope of the heater 18 and 24 is equal to or greater than a preset slope.

According to one embodiment, the controller 12 may control, based on the state of the aerosol-generating article, a power supply time and/or the amount of power supplied to the heater 18 and 24. For example, upon determining that the aerosol-generating article is in an overly moist state using the overly moist state detection sensor (e.g., the sensor unit 13), the controller 12 may increase a time during which power is supplied to the heater 18 and 24 (e.g., a preheating time). According to one embodiment, the controller 12 may control the supply of power to the heater 18 and 24 based on whether the aerosol-generating article is being reused. For example, upon determining that the aerosol-generating article has already been used, the controller 12 may interrupt the supply of power to the heater 18 and 24.

According to one embodiment, the controller 12 may control the supply of power to the heater 18 and 24 based on whether the cartridge has been coupled and/or removed. For example, upon determining that the cartridge has been removed using the cartridge detection sensor (e.g., the sensor unit 13), the controller 12 may interrupt the supply of power to the heater 18 or 24 or may perform control such that power is not supplied to the heater 18 and 24.

According to one embodiment, the controller 12 may control the supply of power to the heater 18 and 24 based on whether the aerosol-generating substance in the cartridge has been exhausted. For example, upon determining that the temperature of the heater 18 and 24 exceeds a limit temperature during preheating of the heater 18 and 24 (i.e., in the preheating section), the controller 12 may determine that the aerosol-generating substance in the cartridge has been exhausted. Upon determining that the aerosol-generating substance in the cartridge has been exhausted, the controller 12 may interrupt the supply of power to the heater 18 and 24. According to one embodiment, the controller 12 may control the supply of power to the heater 18 and 24 based on whether use of the cartridge is possible. For example, upon determining, based on data stored in the memory 17, that the current number of puffs is equal to or greater than the maximum number of puffs set for the cartridge, the controller 12 may determine that use of the cartridge is impossible. Alternatively, when a total time period during which the heater 18 and 24 is heated is equal to or longer than a preset maximum time period or when the total amount of power supplied to the heater 18 and 24 is equal to or greater than a preset maximum amount of power, the controller 12 may determine that use of the cartridge is impossible. In this case, the controller 12 may interrupt the supply of power to the heater 18 or 24 or may perform control such that power is not supplied to the heater 18 and 24.

According to one embodiment, the controller 12 may control the supply of power to the heater 18 and 24 based on the user's puff. For example, the controller 12 may determine whether a puff occurs and/or the intensity of a puff using the puff sensor (e.g., the sensor unit 13). When the number of puffs reaches a preset maximum number of puffs and/or when no puff is detected for a preset time period or longer, the controller 12 may interrupt the supply of power to the heater 18 and 24. When a puff is detected, the controller 12 may control the supply of power to the heater 18 and 24.

According to one embodiment, the controller 12 may control the supply of power to the heater 18 and 24 based on whether the aerosol-generating article (or the cartridge) is authentic and/or the type of the aerosol-generating article (or the cartridge). For example, the controller 12 may determine whether the aerosol-generating article is authentic and/or may determine the type of the aerosol-generating article using the cigarette identification sensor (e.g., the sensor unit 13). In an example, upon determining that the aerosol-generating article (or the cartridge) is inauthentic, the controller 12 may interrupt the supply of power to the heater 18 and 24. Upon determining that the aerosol-generating article (or the cartridge) is authentic, the controller 12 may control (e.g., commence) the supply of power to the heater 18 and 24. In another example, the controller 12 may control the supply of power to the heater 18 and 24 differently depending on the type of the aerosol-generating article (or the cartridge). In more detail, upon determining that the aerosol-generating article (or the cartridge) is a first aerosol-generating article (or a first cartridge), the controller 12 may control the temperature of the heater 18 and 24 and/or power based on a first temperature profile (or a first power profile), and upon determining that the aerosol-generating article (or the cartridge) is a second aerosol-generating article (or a second cartridge), the controller 12 may control the temperature of the heater 18 and 24 and/or power based on a second temperature profile (or a second power profile).

According to one embodiment, the controller 12 may control the output unit 14 based on a result of detection by the sensor unit 13. For example, when the number of puffs counted using the puff sensor (e.g., the sensor unit 13) reaches a preset number, the controller 12 may control the output unit 14 to visually, haptically, and/or audibly provide information that operation of the aerosol-generating device 1 will end soon. For example, the controller 12 may control the output unit 14 to visually, haptically, and/or audibly provide information about the temperature of the heater 18 and 24.

According to one embodiment, based on occurrence of a predetermined event, the controller 12 may store a history of the corresponding event in the memory 17 and may update the history. For example, the event may include events performed in the aerosol-generating device 1, such as detection of insertion of the aerosol-generating article, commencement of heating of the aerosol-generating article, detection of puff, termination of puff, detection of overheating of the heater 18 and 24, detection of application of overvoltage to the heater 18 and 24, termination of heating of the aerosol-generating article, on/off operation of the aerosol-generating device 1, commencement of charging of the power supply 11, detection of overcharging of the power supply 11, and termination of charging of the power supply 11. For example, the history of the event may include the occurrence date and time of the event and log data corresponding to the event. For example, when the predetermined event is detection of insertion of the aerosol-generating article, the log data corresponding to the event may include data on a value detected by the insertion detection sensor (e.g., the sensor unit 13). For example, when the predetermined event is detection of overheating of the heater 18 and 24, the log data corresponding to the event may include data on the temperature of the heater 18 and 24, the voltage applied to the heater 18 and 24, and the current flowing through the heater 18 and 24.

According to one embodiment, the controller 12 may control the communication unit 16 to form a communication link with an external device such as a user's mobile terminal.

According to one embodiment, upon receiving data on authentication from an external device via the communication link, the controller 12 may release restriction on use of at least one function (e.g., a heating function) of the aerosol-generating device 1. For example, the data on authentication may include the user's birthday, an identification number uniquely identifying the user, and whether authentication is completed by the user.

According to one embodiment, the controller 12 may transmit data on the state of the aerosol-generating device 1 (e.g., remaining capacity of the power supply 11 and operation mode) to the external device via the communication link. The transmitted data may be output through a display or the like of the external device.

According to one embodiment, upon receiving a request to search for the location of the aerosol-generating device 1 from the external device via the communication link, the controller 12 may control the output unit 14 to perform an operation corresponding to location search. For example, the controller 12 may perform control such that the haptic unit generates vibration or the display outputs objects corresponding to location search and termination of search.

According to one embodiment, upon receiving firmware data from the external device via the communication link, the controller 12 may perform firmware update.

According to one embodiment, the controller 12 may transmit data on a value detected by the at least one sensor unit 13 to an external server (not shown) via the communication link, and may receive, from the server, and store a learning model generated by learning the detected value through machine learning such as deep learning. The controller 12 may perform the operation of determining the user's puff pattern and the operation of generating the temperature profile using the learning model received from the server.

Although not shown in FIG. 1, the aerosol-generating device 1 may further include a power supply protection circuit. The power supply protection circuit may include at least one switching element, and may block an electric path to the power supply 11 in response to overcharging and/or overdischarging of the power supply 11. The aerosol-generating device 1 may further include a connection interface such as a universal serial bus (USB) interface, and may be connected to other external devices through the connection interface to transmit and receive information or charge the power supply 11.

The aerosol-generating article mentioned in the present disclosure may include at least one aerosol-generating rod (e.g., a medium portion) and at least one filter rod. The heater 18 may be disposed to correspond to the at least one aerosol-generating rod, and may be designed differently depending on the arrangement order and/or positions of the aerosol-generating rod and the filter rod. The aerosol-generating rod may contain at least one of nicotine, an aerosol-generating substance, and an additive. For example, the aerosol-generating substance may include glycerin (e.g., vegetable glycerin (VG)) and/or propylene glycol (PG) and may also include various other substances. For example, the additive may include a flavoring agent and/or an organic acid and may also include various other substances. For example, the aerosol-generating rod may include an aerosol-generating substrate (e.g., a sheet) impregnated with a liquid non-tobacco substance (e.g., an aerosol-generating substance and/or nicotine) and/or may contain a solid tobacco substance (e.g., leaf tobacco and reconstituted tobacco). The tobacco substance may be contained in the aerosol-generating rod in various forms, such as shredded tobacco, granules, and powder. According to one embodiment, the additive of the aerosol-generating rod may include an alkaline substance. Based on the alkaline substance, nicotine contained in the tobacco substance in the aerosol-generating rod may have an alkaline pH (e.g., pH 7.0 or higher). In this case, freebase nicotine may be released from the aerosol-generating rod even at a low temperature. According to one embodiment, the aerosol-generating rod may include two or more aerosol-generating rods, each of which may contain a tobacco substance and/or a non-tobacco substance. Meanwhile, although not shown, the at least one aerosol-generating rod and the at least one filter rod may individually and/or integrally be wrapped by at least one wrapper. In the present disclosure, the aerosol-generating article may be referred to as a stick.

The cartridge mentioned in the present disclosure may contain an aerosol-generating substance having any one state among a liquid state, a solid state, a gaseous state, and a gel state. The aerosol-generating substance may include a liquid composition. For example, the liquid composition may be a liquid containing a tobacco-containing substance including a volatile tobacco flavor component or may be a liquid containing a non-tobacco substance. Meanwhile, the cartridge may include a storage part that contains the aerosol-generating substance and/or a liquid delivery part that is impregnated with (contains) the aerosol-generating substance. For example, the liquid delivery part may include a wick formed of, e.g., cotton fiber, ceramic fiber, glass fiber, or porous ceramic. The cartridge heater 24 may be included in the cartridge in a coil-shaped structure surrounding (or wound around) the liquid delivery part or a structure contacting one side of the liquid delivery part. Alternatively, the cartridge heater 24 may be included in the aerosol-generating device 1, which is removable from the cartridge.

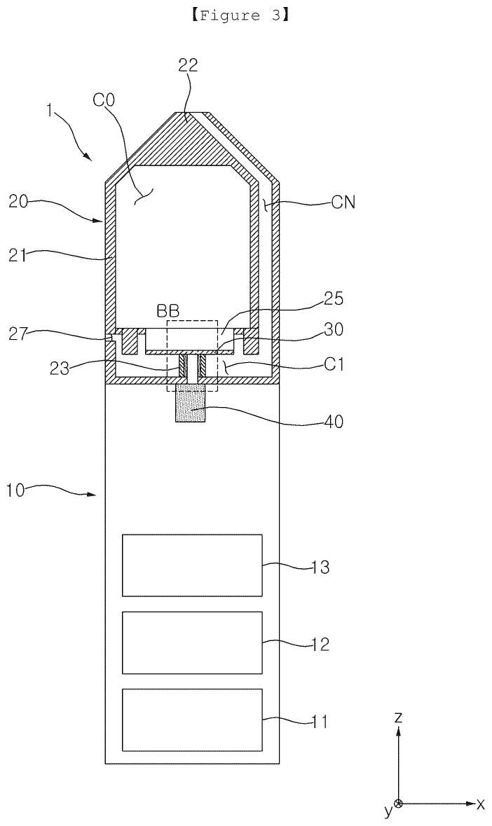

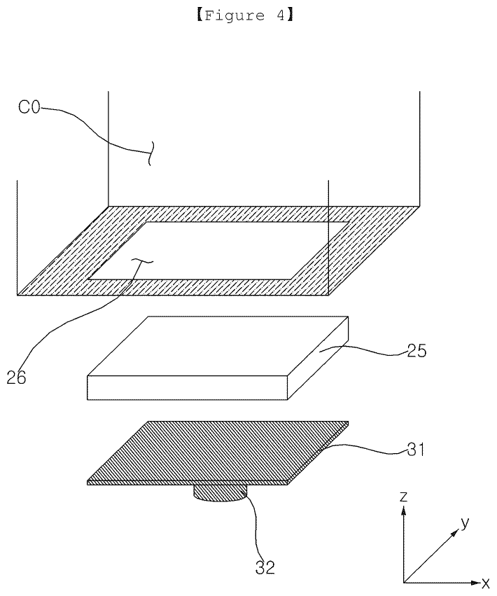

FIG. 2 is a front perspective view of an aerosol-generating device according to an embodiment of the present disclosure, and FIG. 3 is a cross-sectional view of the aerosol-generating device according to the embodiment of the present disclosure when viewed from the front. FIG. 3 shows cross-sections of a body 10 and a cartridge 20 taken along line AA in FIG. 2.

Referring to FIGS. 2 and 3, the aerosol-generating device 1 may include a body 10 and a cartridge 20. The aerosol-generating device 1 may include at least one of a power supply 11, a controller 12, or a sensor 13. At least one of the power supply 11, the controller 12, or the sensor 13 may be disposed inside the body 10. The cartridge 20, which is an aerosol-generating article, may be mounted to the body 10. A user may inhale an aerosol by holding a mouthpiece 22 provided at one end of the cartridge 20 in the mouth.

The cartridge 20 may contain an aerosol-generating substance in an internal storage chamber C0. The aerosol-generating substance may be in the form of a liquid, solid, gas, or gel. The aerosol-generating substance may include a liquid composition. For example, the liquid composition may be a liquid including a tobacco-containing substance that contains a volatile tobacco flavor component, or may be a liquid including a non-tobacco substance.

The cartridge 20 may be assembled with the body 10. The cartridge 20 may be inserted into the body 10 and mounted thereto. The cartridge 20 may be integrally formed with the body 10. Alternatively, the cartridge 20 may be detachably assembled with the body 10.

The body 10 may be configured to allow external air to be introduced into the body 10 while the cartridge 20 is assembled therewith. The external air introduced into the body 10 may flow through the cartridge 20 and then flow toward the user's mouth via an airflow channel CN.

The cartridge 20 may include a storage chamber C0 configured to contain an aerosol-generating substance. The storage chamber C0 may be formed in a cartridge housing 21. A liquid delivery part 25 impregnated with (containing) the aerosol-generating substance may be disposed in the storage chamber C0 or may be disposed in communication with one side of the storage chamber C0. The liquid delivery part 25 may include a wick formed of, for example, cotton fiber, ceramic fiber, glass fiber, or porous ceramic. The liquid delivery part 25 may be referred to as a wick.

A heating element 30 (e.g., the heater 24) may be disposed in the cartridge 20 or the body 10. Although the heating element 30 is illustrated in the drawings as being disposed in the cartridge 20, the disclosure is not limited thereto. The heating element 30 may be disposed in the body 10.

The heating element 30 may be disposed to be separable from the body 10 and/or the cartridge 20. For example, the heating element 30 may be disposed in the body 10 to be separable from the cartridge 20. Alternatively, the heating element 30 may be disposed in the cartridge 20 and may be detachably coupled to the body 10.

The heating element 30 may be in contact with one side of the wick 25. For example, the heating element 30 may be disposed below the wick 25 and may be in contact with a lower surface of the wick 25. The aerosol-generating substance impregnated in the wick 25 may move toward the heating element 30 along the wick 25. The wick 25 may deliver the aerosol-generating substance stored in the storage chamber C0 to the heating element 30.

The heating element 30 may generate heat using light incident thereon from the outside. The heating element 30 may include metallic nanoparticles that generate heat through surface plasmon resonance (SPR). For example, the metallic nanoparticles may be metallic particles having a diameter in the nanometer range. The heating element 30 may be referred to as an SPR heating element or an SPR heater. If light reaches or is incident on one side of the heating element 30 from the outside, free electrons on the metal surface included in the heating element 30 may collectively oscillate due to resonance with the electromagnetic field of the light having a specific energy. Through this surface plasmon resonance phenomenon, heat may be generated in the metallic nanoparticles included in the heating element 30. In this way, the heating element 30 may produce heat.

The metallic particles of the heating element 30 may be formed of a material suitable for generating heat through interaction with light. For example, the metallic particles may include at least one of gold, silver, copper, palladium, or platinum or may include combinations thereof.

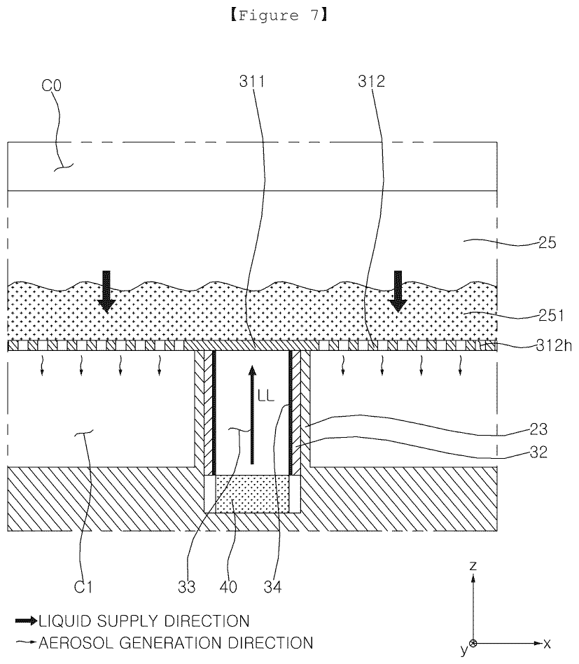

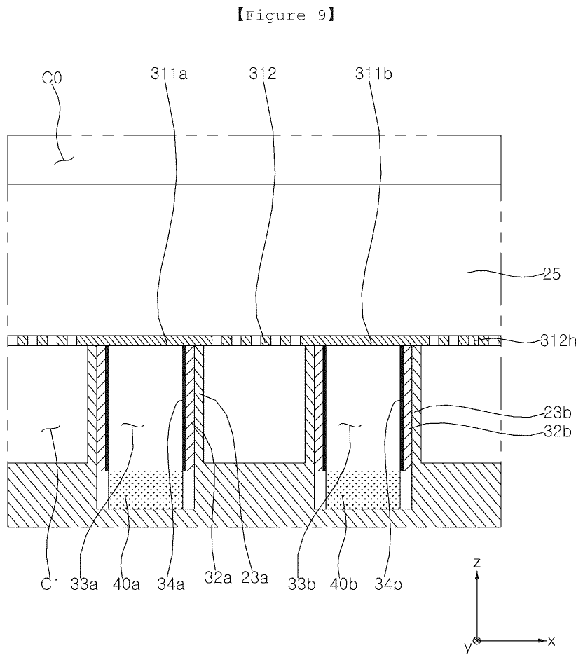

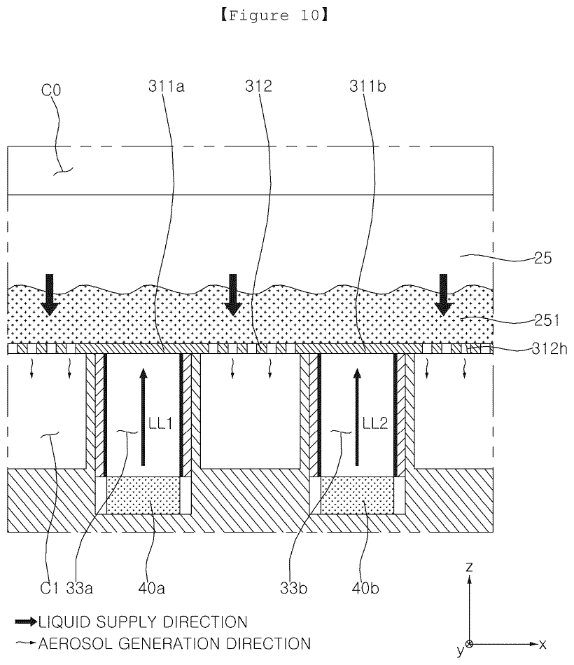

A light source 40 may be disposed in the cartridge 20 or the body 10. The light source 40 may emit light LL (see FIGS. 6 and 9) using power supplied from the power supply 11. For example, the light source 40 may include a laser element configured to emit light having a designated wavelength. The light source 40 may emit light in a wavelength range corresponding to the average maximum absorbance of the type of metallic particles contained in the heating element 30. For example, if the metallic particles are gold (Au), the light source 40 may emit light having a wavelength of approximately 600 nm to approximately 650 nm. For example, if the metallic particles are silver (Ag), the light source 40 may emit light having a wavelength of approximately 420 nm to approximately 470 nm.

The light source 40 may face the heating element 30. For example, the light LL emitted from the light source 40 may travel toward the heating element 30 and may reach at least a portion of the heating element 30.

The airflow channel CN may be provided in the cartridge 20. The airflow channel CN may be in communication with an atomization chamber C1, in which the heating element 30 or the wick 25 is disposed, and with the outside of the cartridge 20. One end of the airflow channel CN may be open to the atomization chamber C1, and the other end thereof may be in communication with the mouthpiece 22. For example, the airflow channel CN may be elongated in the longitudinal direction of the cartridge 20 on one side of the storage chamber C0 of the cartridge 20. Meanwhile, although not shown in the drawings, the airflow channel CN may be elongated through the storage chamber C0 of the cartridge 20 in the longitudinal direction of the cartridge 20.

An inlet 27 may be provided in the cartridge 20. The inlet 27 may be formed by one side of the cartridge housing 21 being open. The inlet 27 may be in communication with the atomization chamber C1. The inlet 27 may be open in one direction from the atomization chamber C1 and may be disposed opposite the airflow channel CN with respect to the atomization chamber C1. External air introduced through the inlet 27 may pass through the atomization chamber C1 and may flow into the airflow channel CN.

As the wick 25 is heated by the heating element 30, an aerosol may be generated. The generated aerosol may be mixed with external air introduced into the atomization chamber C1 through the inlet 27, and the resulting mixture may flow through the airflow channel CN and may be inhaled to the user's mouth via the mouthpiece 22.

The power supply 11 may supply power to operate components of the aerosol-generating device 1. The power supply 11 may be referred to as a battery. The power supply 11 may supply power to at least one of the controller 12, the sensor 13, or the light source 40.

The controller 12 may control overall operation of the aerosol-generating device 1. The controller 12 may be mounted on a printed circuit board (PCB). The controller 12 may control operation of at least one of the power supply 11, the sensor 13, or the light source 40.

The controller 12 may analyze a result of detection by the sensor 13 and may control subsequent processes. For example, the controller 12 may control, based on the result of detection by the sensor 13, power supplied to the light source 40 so that operation of the light source 40 commences or ends. For example, the controller 12 may control, based on the result of detection by the sensor 13, the amount of power supplied to the light source 40 and a power supply time so that the heating element 30 is heated to a predetermined temperature or is maintained at an appropriate temperature. The sensor 13 may include at least one of a temperature sensor, a puff sensor, or a cartridge detection sensor. For example, the sensor 13 may detect at least one of the temperature of the heating element 30, the temperature of the light source 40, the temperature of the power supply 11, or the internal/external temperature of the body 10. For example, the sensor 13 may detect a user puff. For example, the sensor 13 may detect whether the cartridge 20 is mounted.

FIG. 4 is an exploded perspective view of the storage chamber, the wick, and the heating element of the aerosol-generating device according to the embodiment of the present disclosure.

Referring to FIG. 4, a wick hole 26 may be formed in one side of the storage chamber C0. The wick 25 may be disposed on one side of the storage chamber C0. One side of the wick 25 may be exposed to the inside of the storage chamber C0 through the wick hole 26. For example, the wick 25 may be disposed below the storage chamber C0, and at least a portion of the upper surface of the wick 25 may be exposed to the inside of the storage chamber C0 through the wick hole 26 formed in the lower side of the storage chamber C0.

The heating element 30 may be in contact with the wick 25. The heating element 30 may be elongated in the extending direction of the wick 25 (e.g., the x-direction or the y-direction). The heating element 30 may be disposed below the wick 25, and at least a portion of the upper surface of the heating element 30 may be in contact with at least a portion of the lower surface of the wick 25.

The heating element 30 may include a heating plate 31 and a light guide 32. At least a portion of the heating plate 31 may generate heat using the light LL that is emitted from the light source 40 and reaches the heating plate 31. The light guide 32 may extend from the heating plate 31 in one direction. The light guide 32 may define an optical path along which the light emitted from the light source 40 travels toward the heating plate 31.

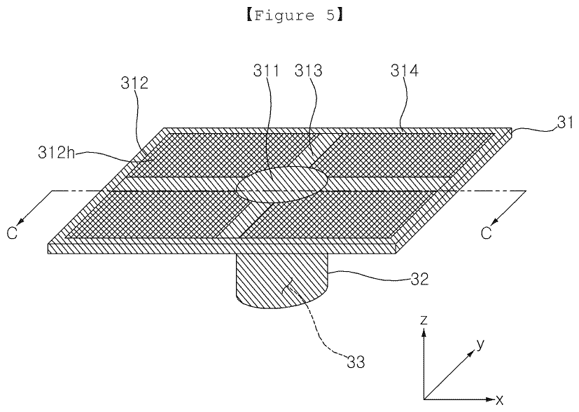

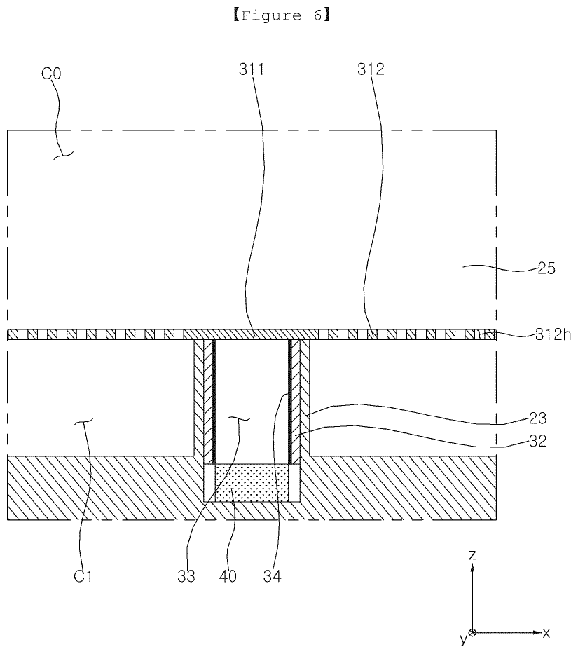

FIG. 5 is a perspective view showing the heating element of the aerosol-generating device according to the embodiment of the present disclosure.

Referring to FIG. 5, the heating element 30 may include a heating plate 31 and a light guide 32.

The heating plate 31 may include a first part 311 and a second part 312. The first part 311 may be disposed at or near the center of the heating plate 31. The first part 311 may have a flat plate shape. For example, the first part 311 may be a polygonal, circular, or elliptical plate. The first part 311 may extend in the extending direction of the heating plate 31 (e.g., the x-direction or the y-direction). The first part 311 may have a plate shape that is closed in the thickness direction of the heating plate 31. That is, the first part 311 may not include a structure such as a hole through which light may pass.

The first part 311 may be disposed at a position to which the light LL emitted from the light source 40 travels. For example, the first part 311 may be disposed to overlap the light guide 32 in a direction intersecting the longitudinal direction of the heating plate 31 (e.g., in the z-direction). One surface of the first part 311 may be located within the light guide 32. For example, the lower surface of the first part 311 may be disposed within a guide groove 33 formed in the light guide 32 and may define at least a portion of the upper surface of the guide groove 33.

The second part 312 may be disposed outside the first part 311. The second part 312 may surround the first part 311. The second part 312 may extend in the extending direction of the heating plate 31. The second part 312 may extend outward from the first part 311. The second part 312 may be disposed at a position to which the light LL emitted from the light source 40 does not travel. For example, the second part 312 may be disposed not to overlap the light guide 32 in a direction intersecting the longitudinal direction of the heating plate 31. The second part 312 may be integrally formed with the first part 311.

The second part 312 may include a plurality of holes 312h formed therein. The plurality of holes 312h may be spaced apart from each other. The plurality of holes 312h may penetrate the second part 312 in the thickness direction of the heating plate 31. For example, the second part 312 may be a metal mesh in which the plurality of holes 312h is formed.

The light guide 32 may extend from the heating plate 31 in one direction. The light guide 32 may extend toward the light source 40. The light guide 32 may include a guide groove 33 formed therein. For example, the light guide 32 may be a hollow tube extending downward from the heating plate 31. One surface of the first part 311 may be disposed within the light guide 32. The light guide 32 may surround one surface of the first part 311. For example, the guide groove 33 in the light guide 32 may be open downward, and one surface of the first part 311 may be disposed on the upper side of the light groove 33. One surface of the first part 311 disposed within the light guide 32 may be referred to as a light receiving portion. The light guide 32 may define a path along which light travels. For example, the guide groove 33 in the light guide 32 may define a path along which light travels from the lower opening thereof to one surface of the first part 311 disposed on the upper side thereof.

The heating plate 31 may include at least one of a third part 313 or a fourth part 314. The third part 313 may be connected to at least one of the first part 311 or the second part 312. The third part 313 may extend outward across the second part 312 from the first part 311. The third part 313 may extend in the extending direction of the heating plate 31. The third part 313 may be provided in plural. For example, the third part 313 may include a plurality of plates extending radially from the first part 311. The third part 313 may have a plate shape that is closed in the thickness direction of the heating plate 31. The third part 313 may not include a structure such as a hole through which light may pass. The third part 313 may be integrally formed with the first part 311 and the second part 312.

The fourth part 314 may be connected to at least one of the second part 312 or the third part 313. The fourth part 314 may extend along the periphery of the second part 312. The fourth part 314 may define an outer edge of the heating plate 31. The fourth part 314 may have a plate shape that is closed in the thickness direction of the heating plate 31. The fourth part 314 may not include a structure such as a hole through which light may pass. The fourth part 314 may be integrally formed with the second part 312 and the third part 313.

Although not shown in the drawings, the fourth part 314 may extend along the periphery of the second part 312 and may extend in a direction intersecting the extending direction of the heating plate 31. For example, the fourth part 314 may extend along the periphery of the second part 312 and may be bent upward and extend above the heating plate 31. The fourth part 314 may be in contact with a lower edge of the wick 25 disposed above the heating plate 31. The fourth part 314 may be in contact with a portion of the outer surface of the wick 25 and may surround a portion of the outer surface of the wick 25.

If the light LL emitted from the light source 40 reaches the heating plate 31, the first part 311 on which the light LL is directly incident may generate heat. The heat generated in the first part 311 may be transferred to the second to fourth parts 312, 313, and 314. The third part 313, which extends outward across the second part 312 from the first part 311, may facilitate the transfer of heat generated in the first part 311 to the second part 312. Due to the fourth part 314, which is in contact with the lower edge and/or a portion of the outer surface of the wick 25, the aerosol-generating substance impregnated in the peripheral region of the wick 25 may be heated.

Accordingly, the transfer of heat from the region directly heated by the light to the surrounding regions may be increased, and heating efficiency may be improved.

FIG. 6 is an enlarged cross-sectional view showing the arrangement of the storage chamber, the wick, and the heating element in the aerosol-generating device according to the embodiment of the present disclosure, and FIG. 7 is a cross-sectional view showing an optical path and an aerosol generation direction in the aerosol-generating device according to the embodiment of the present disclosure. FIGS. 6 and 7 are enlarged cross-sectional views of region BB of the cartridge 20 shown in FIG. 3, taken along line CC in FIG. 5.

Referring to FIG. 6 together with FIG. 3, the light source 40 may be disposed opposite the wick 25 with respect to the heating element 30. The wick 25 may be disposed above the heating plate 31, and the light source 40 may be disposed below the heating plate 31. The light source 40 may be disposed to face the heating plate 31. The light source 40 may be disposed to face one surface of the first part 311 of the heating plate 31.

The light source accommodating portion 23 may surround the light source 40 and may be elongated in one direction. The light source 40 may be disposed in the light source accommodating portion 23. The light source accommodating portion 23 may be elongated toward the first part 311 of the heating plate 31. For example, the light source accommodating portion 23 may be a hollow tube extending upward from the body 10. The light source accommodating portion 23 may have an open top. The light source 40 may be disposed on the bottom of the light source accommodating portion 23 and may face the open top of the light source accommodating portion 23.

The light guide 32 may be coupled to the light source accommodating portion 23. The light guide 32 may be press-fitted into the light source accommodating portion 23. The light source accommodating portion 23 may seal the interior of the light guide 32 from the outside. A space defined by the coupling of the light guide 32 and the light source accommodating portion 23 may be sealed from the outside. The light source 40 may be disposed in the space defined by the coupling of the light guide 32 and the light source accommodating portion 23.

Accordingly, the light emitted from the light source 40 may be prevented from leaking to the wick 25 or the outside of the aerosol-generating device 1.

A reflector 34 may be provided in the light guide 32. The reflector 34 may be disposed on an inner surface of the light guide 32. The reflector 34 may cover at least a portion of the inner surface of the light guide 32. The reflector 34 may reflect the light LL emitted from the light source 40. For example, the reflector 34 may reflect the light LL emitted from the light source 40 toward the first part 311. The reflector 34 may be formed of a material suitable for reflecting the light LL. For example, the reflector 34 may be formed of a metallic material. For example, the reflector 34 may include at least one of gold, silver, or copper.

Accordingly, the light emitted from the light source 40 may be concentrated on the heating element 30, and thus heating efficiency may be improved.

The atomization chamber C1 may be disposed opposite the wick 25 with respect to the heating plate 31. For example, the atomization chamber C1 may be located below the heating plate 31. The atomization chamber C1 may surround the outer side of the light guide 32. The light guide 32 may be disposed in the atomization chamber C1. The atomization chamber C1 may be elongated in the extending direction of the heating plate 31.

The second part 312 may define at least a portion of the atomization chamber C1. The plurality of holes 312h formed in the second part 312 may be in communication with the storage chamber C0 and the atomization chamber C1. The plurality of holes 312h may be disposed within the storage chamber C0 and may face the wick 25 that is in contact with the heating plate 31. One surface of the wick 25 may be in contact with the first part 311 and the second part 312. The surface of the wick 25 that is in contact with the second part 312 may be exposed to the interior of the atomization chamber C1 through the plurality of holes 312h.

The plurality of holes 312h may be disposed not to overlap the light guide 32 in the thickness direction of the heating plate 31 or in the longitudinal direction of the light guide 32. The plurality of holes 312h may be disposed outside the light guide 32 in the longitudinal direction of the heating plate 31.

Referring to FIG. 7 together with FIG. 3, the wick 25 may be impregnated with an aerosol-generating substance 251. The aerosol-generating substance 251 may move to a lower side of the wick 25 due to gravity. The aerosol-generating substance 251 may be primarily located at a portion of the wick 25 that is in contact with the heating plate 31 or in a region near the contact portion. A portion of the aerosol-generating substance 251 may move to the lower side of the wick 25 and may be retained in the plurality of holes 312h formed in the heating plate 31.

The light LL emitted from the light source 40 may reach or be incident on the heating plate 31. The light LL emitted from the light source 40 may reach or be incident on the lower surface of the first part 311 of the heating plate 31. The first part 311 may generate heat using the light LL. The first part 311 may generate heat through a surface plasmon resonance phenomenon.

The heat generated in the first part 311 may be transferred to the second part 312. The first part 311 and the second part 312 may heat the wick 25. The aerosol-generating substance 251 located at a portion of the wick 25 that is in contact with the heating plate 31 or in a region near the contact portion may be heated by the first part 311 and the second part 312, thereby generating an aerosol. The aerosol-generating substance 251 located in the plurality of holes 312h may be heated by the second part 312, thereby generating an aerosol.

The generated aerosol may flow into the atomization chamber C1 through the plurality of holes 312h in the second part 312. The aerosol may be mixed with external air introduced through the inlet 27 positioned on one side of the atomization chamber C1. The aerosol mixed with external air may pass through the airflow channel CN disposed on the opposite side of the atomization chamber C1 and may flow to the outside of the device through the mouthpiece 22.

As described above, the aerosol-generating substance may be easily supplied to the heating plate 31 through the plurality of holes 312h, which is formed outside the optical path and through which the wick 25 and the atomization chamber C1 communicate with each other, and the generated aerosol may easily flow to the airflow channel CN through the plurality of holes 312h. Accordingly, the amount of aerosol generated may be increased.

In addition, a portion of the heating plate 31 on which the light LL is incident may be sealed to prevent the light LL from being emitted outside, and a portion extending outward from the portion on which the light LL is incident may be exposed to the atomization chamber C1. Accordingly, the heating efficiency of the heating element 30 may be improved.

Furthermore, because the optical path is isolated from the atomization chamber C1 through which the aerosol flows, it may be possible to prevent a portion of the light LL traveling toward the heating plate 31 from being blocked by the aerosol or the aerosol-generating substance flowing in the atomization chamber C1, thereby improving the heating efficiency of the heating element 30.

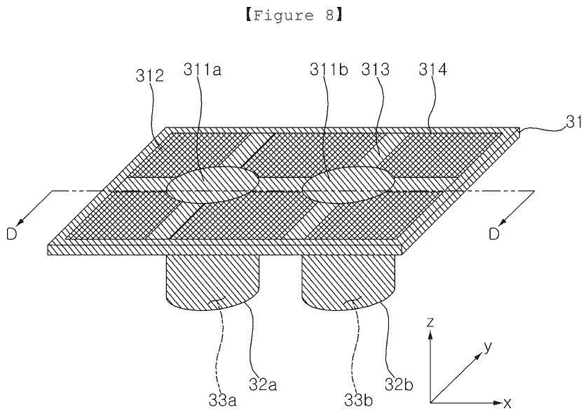

FIG. 8 is a perspective view showing a heating element of an aerosol-generating device according to another embodiment of the present disclosure, FIG. 9 is an enlarged cross-sectional view showing the arrangement of the storage chamber, the wick, and the heating element in the aerosol-generating device according to the other embodiment of the present disclosure, and FIG. 10 is a cross-sectional view showing an optical path and an aerosol generation direction in the aerosol-generating device according to the other embodiment of the present disclosure. FIGS. 9 and 10 are enlarged cross-sectional views of region BB of the cartridge 20 shown in FIG. 3, taken along line DD in FIG. 8. Detailed descriptions of the features in FIGS. 8 to 10 that are identical to those described with reference to FIGS. 5 to 7 will be omitted.

Referring to FIG. 8, the heating plate 31 may include a plurality of first parts 311a and 311b spaced apart from each other. The plurality of first parts 311a and 311b may be disposed inside the heating plate 31. Each of the plurality of first parts 311a and 311b may have a flat plate shape. Each of the plurality of first parts 311a and 311b may have a plate shape that is closed in the thickness direction of the heating plate 31.

The heating plate 31 may include a plurality of light guides 32a and 32b. Each of the plurality of light guides 32a and 32b may extend from the heating plate 31 toward the light source 40. Each of the plurality of light guides 32a and 32b may surround one surface of a respective one of the plurality of first parts 311a and 311b. The plurality of light guides 32a and 32b may include guide grooves 33a and 33b formed therein, respectively. Each of the guide grooves 33a and 33b may define a path along which light travels from a lower opening thereof to one surface of a respective one of the first parts 311a and 311b disposed on the upper side thereof.

A second part 312 may be disposed outside the plurality of first parts 311a and 311b. The second part 312 may surround the plurality of first parts 311a and 311b. The second part 312 may be disposed at a position to which the light emitted from the light source 40 does not travel. The second part 312 may include a plurality of holes 312h spaced apart from each other.

The heating plate 31 may include at least one of a third part 313 or a fourth part 314. The third part 313 may be provided in plural. For example, the third part 313 may include a plurality of plates extending radially from the plurality of first parts 311a and 311b. For example, the third part 313 may include plates interconnecting the plurality of first parts 311a and 311b. The third part 313 may be integrally formed with the first parts 311a and 311b and the second part 312.

The fourth part 314 may extend along the periphery of the second part 312. The fourth part 314 may be integrally formed with the second part 312 and the third part 313.

The third part 313 and the fourth part 314 may have a plate shape that is closed in the thickness direction of the heating plate 31. The third part 313 and the fourth part 314 may not include a structure such as a hole through which light may pass.

Referring to FIGS. 9 and 10 together with FIG. 3, the light source 40 may include a plurality of light sources 40a and 40b that is disposed to face the plurality of first parts 311a and 311b, respectively, and emits light toward the plurality of first parts 311a and 311b, respectively. Each of the plurality of light sources 40a and 40b may be disposed to face one surface of a respective one of the plurality of first parts 311a and 311b of the heating plate 31.

The plurality of light sources 40a and 40b may be accommodated in light source accommodating portions 23a and 23b, respectively. The light source accommodating portions 23a and 23b may be defined as separate spaces, in each of which a respective one of the light sources 40a and 40b is accommodated.

The light guides 32a and 32b may be coupled to the light source accommodating portions 23a and 23b, respectively. Spaces defined by the coupling of the light guides 32a and 32b and the light source accommodating portions 23a and 23b may be sealed from the outside. The light sources 40a and 40b may be disposed in the spaces defined by the coupling of the light guides 32a and 32b and the light source accommodating portions 23a and 23b, respectively. Reflectors 34a and 34b may be provided in the light guides 32a and 32b, respectively.

The atomization chamber C1 may surround the outer sides of the plurality of light guides 32a and 32b. The plurality of holes 312h may be disposed not to overlap the plurality of light guides 32a and 32b in the thickness direction of the heating plate 31 or in the longitudinal direction of the light guides 32a and 32b. The plurality of holes 312h may be disposed outside the plurality of light guides 32a and 32b in the longitudinal direction of the heating plate 31.

The lights LL1 and LL2 emitted from the light sources 40a and 40b may reach or be incident on the lower surfaces of the first parts 311a and 311b, respectively. The plurality of first parts 311a and 311b may generate heat using the lights LL1 and LL2. The heat generated in the plurality of first parts 311a and 311b may be transferred to the second part 312. In this way, because the plurality of first parts 311a and 311b, on which the lights LL1 and LL2 emitted from the plurality of light sources 40a and 40b are incident, is disposed to be spaced apart from each other, the area of a portion of the heating element 30 that is directly heated by the light may be increased, and heating efficiency may be improved.

The controller 12 may control the light source 40. The controller 12 may control on/off operation of the light source 40 and/or power supplied to the light source 40. The controller 12 may control the number of light sources emitting light among the plurality of light sources 40a and 40b or power supplied to the plurality of light sources 40a and 40b based on a target temperature or a target heating rate of the heating element 30. For example, if the target temperature of the heating element 30 is equal to or higher than a predetermined temperature, the controller 12 may increase the number of light sources emitting light among the plurality of light sources 40a and 40b or may control the power supply 11 to increase the power supplied to the plurality of light sources 40a and 40b. For example, if the target temperature of the heating element 30 is lower than the predetermined temperature, the controller 12 may reduce the number of light sources emitting light among the plurality of light sources 40a and 40b or may control the power supply 11 to reduce the power supplied to the plurality of light sources 40a and 40b. For example, if the target heating rate of the heating element 30 is equal to or higher than a predetermined value, the controller 12 may increase the number of light sources emitting light among the plurality of light sources 40a and 40b or may control the power supply 11 to increase the power supplied to the plurality of light sources 40a and 40b. For example, if the target heating rate of the heating element 30 is lower than the predetermined value, the controller 12 may reduce the number of light sources emitting light among the plurality of light sources 40a and 40b or may control the power supply 11 to reduce the power supplied to the plurality of light sources 40a and 40b.

In this way, because the operation of the plurality of light sources 40a and 40b emitting light toward the heating element 30 is controlled, the target temperature or the target heating rate of the heating element 30 may be accurately controlled.

As described above, according to at least one of the embodiments of the present disclosure, because the SPR heating element includes the first part on which light emitted from the light source is incident and the second part disposed outside the first part and having a plurality of holes formed therein, the heating element may be heated through a portion on which the light is concentratedly incident, and thus heating efficiency may be improved.

According to at least one of the embodiments of the present disclosure, because the SPR heating element includes a plurality of holes formed in a region outside the optical path and allowing the wick and the atomization chamber to communicate with each other therethrough, the aerosol-generating substance may be supplied to the heating element through the plurality of holes, and the generated aerosol may easily flow into the airflow channel through the plurality of holes. Accordingly, the amount of aerosol generated may be increased.

According to at least one of the embodiments of the present disclosure, because the SPR heating element includes the third part extending outward from the first part, on which light is incident, across the second part having the plurality of holes, the transfer of heat from the region directly heated by the light to the surrounding regions may be increased, and heating efficiency may be improved.

According to at least one of the embodiments of the present disclosure, due to the structure that surrounds the first part, on which light is incident, and extends from the first part toward the light source to seal the optical path from the outside, leakage of the light to the outside of the device may be prevented, and the light may be concentrated on the heating element. Accordingly, heating efficiency may be improved.

According to at least one of the embodiments of the present disclosure, because the SPR heating element includes the plurality of first parts, on each of which light emitted from a respective one of the plurality of light sources is incident and which is disposed to be spaced apart from each other, the area of a portion of the heating element that is directly heated by the light may be increased, and heating efficiency may be improved.

According to at least one of the embodiments of the present disclosure, because the operation of the plurality of light sources emitting light toward the heating element is controlled, the target temperature or the target heating rate of the heating element may be accurately controlled.

Referring to FIGS. 1 to 10, an aerosol-generating device 1 in accordance with one aspect of the present disclosure may include a storage chamber C0 storing an aerosol-generating substance, a wick 25 that is in communication with the storage chamber C0, a heating element 30 that is in contact with the wick 25 and contains nanoparticles generating heat through surface plasmon resonance, and a light source 40 configured to emit light toward the heating element 30. The heating element 30 may include a first part 311 receiving light emitted from the light source 40 and a second part 312 disposed outside the first part 311 and having a plurality of holes 312h formed therein.

In addition, in accordance with another aspect of the present disclosure, the heating element 30 may include a heating plate 31 elongated in one direction and including the first part 311 and the second part 312 and a light guide 32 extending from the heating plate 31 toward the light source 40 and having a path defined therein to guide travel of light emitted from the light source 40.

In addition, in accordance with another aspect of the present disclosure, the light guide 32 may surround a light-receiving surface of the first part 311 and may extend from the light-receiving surface in a direction intersecting with the longitudinal direction of the heating plate 31.

In addition, in accordance with another aspect of the present disclosure, the light guide 32 may include a reflector 34 disposed on an inner surface of the light guide 32 and configured to reflect light.

In addition, in accordance with another aspect of the present disclosure, the light source 40 may be disposed to face the wick 25 with respect to the heating element 30.

In addition, in accordance with another aspect of the present disclosure, the aerosol-generating device may include a light source accommodating portion 23 accommodating the light source 40 and coupled to the light guide 32 to seal the interior of the light guide 32 and prevent light emitted from the light source 40 from leaking outside the light guide 32.

In addition, in accordance with another aspect of the present disclosure, the aerosol-generating device may include an atomization chamber C1 disposed to face the wick 25 with respect to the heating plate 31 and surrounding an outer side of the light guide 32. The plurality of holes 312h may be in communication with the wick 25 and the atomization chamber C1 and may be disposed outside the light guide 32 in the longitudinal direction of the heating plate 31.

In addition, in accordance with another aspect of the present disclosure, the aerosol-generating device may include an inlet 27 formed to be open from the atomization chamber C1 toward one side in the longitudinal direction of the heating plate 31 and an airflow channel CN disposed to face the inlet 27 with respect to the atomization chamber C1.

In addition, in accordance with another aspect of the present disclosure, the heating element 30 may include a third part 313 extending outward from the first part 311 across the second part 312.

In addition, in accordance with another aspect of the present disclosure, the heating element 30 may include a plurality of third parts 313 extending radially from the first part 311.

In addition, in accordance with another aspect of the present disclosure, the heating element 30 may include a fourth part 314 formed along the periphery of the second part 312 and connected to the second part 312 and the third part 313.

In addition, in accordance with another aspect of the present disclosure, the heating element 30 may include a plurality of first parts 311a and 311b spaced apart from each other, and the second part 312 may be disposed outside the plurality of first parts 311a and 311b.

In addition, in accordance with another aspect of the present disclosure, the light source 40 may include a plurality of light sources disposed to face the plurality of first parts 311a and 311b, respectively. The plurality of light sources may emit light toward the plurality of first parts 311a and 311b, respectively.

In addition, in accordance with another aspect of the present disclosure, the aerosol-generating device may include a controller 12 configured to control the light source 40. The controller 12 may be configured to control the number of light sources emitting light among the plurality of light sources based on a target temperature or a target heating rate of the heating element 30.

Certain embodiments or other embodiments of the disclosure described above are not mutually exclusive or distinct from each other. Any or all elements of the embodiments of the disclosure described above may be combined with another or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An aerosol-generating device comprising:
a storage chamber storing an aerosol-generating substance;
a wick in communication with the storage chamber;
a heating element in contact with the wick, the heating element containing nanoparticles generating heat through surface plasmon resonance; and
a light source configured to emit light toward the heating element,
wherein the heating element comprises:
a first part receiving light emitted from the light source; and
a second part disposed outside the first part, the second part having a plurality of holes formed therein.

2. The aerosol-generating device according to claim 1, wherein the heating element comprises:
a heating plate elongated in a one direction, the heating plate comprising the first part and the second part; and
a light guide extending from the heating plate toward the light source, the light guide having a path defined therein to guide travel of light emitted from the light source.

3. The aerosol-generating device according to claim 2, wherein the light guide surrounds a light-receiving surface of the first part and extends from the light-receiving surface in a direction intersecting with a longitudinal direction of the heating plate.

4. The aerosol-generating device according to claim 3, wherein the light guide comprises a reflector disposed on an inner surface of the light guide, the reflector being configured to reflect light.

5. The aerosol-generating device according to claim 3, wherein the light source is disposed to face the wick with respect to the heating element.

6. The aerosol-generating device according to claim 2, comprising a light source accommodating portion accommodating the light source, the light source accommodating portion being coupled to the light guide to seal an interior of the light guide and prevent light emitted from the light source from leaking outside the light guide.

7. The aerosol-generating device according to claim 2, comprising an atomization chamber disposed to face the wick with respect to the heating plate and surrounding an outer side of the light guide,
wherein the plurality of holes are in communication with the wick and the atomization chamber and are disposed outside the light guide in a longitudinal direction of the heating plate.

8. The aerosol-generating device according to claim 7, comprising:
an inlet formed to be open from the atomization chamber toward one side in the longitudinal direction of the heating plate; and
an airflow channel disposed to face the inlet with respect to the atomization chamber.

9. The aerosol-generating device according to claim 1, wherein the heating element comprises a third part extending outward from the first part across the second part.

10. The aerosol-generating device according to claim 9, wherein the heating element comprises a plurality of third parts extending radially from the first part.

11. The aerosol-generating device according to claim 9, wherein the heating element comprises a fourth part formed along a periphery of the second part and connected to the second part and the third part.

12. The aerosol-generating device according to claim 1, wherein the heating element comprises a plurality of first parts spaced apart from each other, and
wherein the second part is disposed outside the plurality of first parts.

13. The aerosol-generating device according to claim 12, wherein the light source comprises a plurality of light sources disposed to face the plurality of first parts, respectively, the plurality of light sources being configured to emit light toward the plurality of first parts, respectively.

14. The aerosol-generating device according to claim 13, comprising a controller configured to control the light source,
wherein the controller is configured to control a number of light sources emitting light among the plurality of light sources based on a target temperature or a target heating rate of the heating element.
